(19) United States
(12) Patent Application Publication
(10) Pub. No.: US 2025/0209228 A1
(43) Pub. Date: Jun. 26, 2025

(54) SPATIAL ADHESIVE MAPPING METHODS AND SYSTEMS FOR A VEHICLE MANUFACTURING PROCESS

(71) Applicant: Volvo Car Corporation, Göteborg (SE)

(72) Inventor: David Joiner, Summerville, SC (US)

(21) Appl. No.: 18/390,039

(22) Filed: Dec. 20, 2023

(51) Int. Cl. G06F 30/15; B05C 5/02

(52) U.S. Cl. CPC G06F 30/15; B05C 5/0212

(57) ABSTRACT

A spatial adhesive mapping method, including: identifying a part of a vehicle; applying an adhesive bead to the part; generating a three-dimensional adhesive map of the adhesive bead; and comparing the three-dimensional adhesive map to a three-dimensional adhesive envelope to determine if the adhesive bead is acceptable or unacceptable. The spatial adhesive mapping method may further include: performing a teardown inspection of the part to determine if the adhesive bead is acceptable or unacceptable; validating the three-dimensional adhesive envelope when it is determined that the adhesive bead is acceptable based on the teardown inspection; and modifying the three-dimensional adhesive envelope when it is determined that the adhesive bead is unacceptable based on the teardown inspection.

### TECHNICAL FIELD

The present disclosure relates generally to the vehicle manufacturing field. More particularly, the present disclosure relates to spatial adhesive mapping methods and systems for a vehicle manufacturing process.

### BACKGROUND

Current quality loops for applying adhesive beads in vehicle manufacturing processes involve applying an adhesive bead to a part in conformance with a predetermined specification in terms of location and volume. The adhesive bead between sheets of metal, for example, prevents water intrusion, minimizes flutter, and enhances crash safety. In order to verify nominal compliance, teardown of the part or a vehicle is required, at least on a periodic basis, as it is not practically possible to see an adhesive bead between sheets of metal. If problems are encountered, the predetermined specification may then be manually updated such that future problems are hopefully avoided. Imaging and location sensors and systems may be used to monitor in-process specification compliance in a rudimentary two-dimensional (2D) fashion, in terms of an adhesive bead being applied to a sheet of metal in the proper location and volume. Other quality loops in vehicle manufacturing processes and other applications currently operate in a similar manner. These quality loops are thus undesirably time consuming and inefficient, requiring regular teardowns and being slow to ensure product quality. Further, when nominal non-compliance is discovered, it is often relatively difficult to determine which products may be similarly affected.

The present background is provided as illustrative context only and should not be construed to be limiting in any manner. It will be readily apparent to those of ordinary skill in the art that the principles and concepts of the present disclosure may be implemented in other contexts equally, without limitation.

### SUMMARY

The present disclosure provides improved spatial adhesive mapping methods and systems. The principles and concepts of the present disclosure may be applied in other vehicle manufacturing and other contexts as well. Using imaging and location sensors and systems, the spatial adhesive mapping methods and systems of the present disclosure map, in three dimensions, applied adhesive beads as they are applied on identified parts. These stored three-dimensional (3D) adhesive bead maps are compared to nominal maps. Periodic teardowns are then used to identify problems and adjust the nominal maps as appropriate. In this manner, big data may be used to improve quality constantly over time. Imaging and visual aids are used to ensure location and volume accuracy in real time, and stored maps are used to provide feedback that enhances quality over time. The need for teardowns is minimized and problems and affected products can be identified and remedied or recalled more quickly.

Instead of simply monitoring an applied adhesive bead in terms of location and volume and checking the accuracy and effectiveness of such applied adhesive beads periodically via teardowns, the spatial adhesive mapping methods and systems of the present disclosure generate 3D adhesive bead maps for each identified part as applied, in real time, in terms of location and volume (including height, width, and shape). These 3D adhesive bead maps are stored and compared to nominal maps to ensure ongoing 3D envelope compliance. If a 3D adhesive bead map is out of compliance, a teardown may be performed. If the teardown results are subsequently determined to be unacceptable, then the associated part may be scrapped, along with all similar identified parts having similar 3D adhesive bead maps. If the teardown results are subsequently determined to be acceptable, then the associated part may be used and the nominal 3D envelope may be updated and used as a standard for subsequent parts. In this manner, feedback is used to provide and ensure an optimal nominal 3D envelope in real time and over time-replacing the conventional 2D location and volume (i.e., adhesive cylinder displacement) monitoring methodology versus a static predetermined specification. A library of pass/fail product configurations is thus efficiently created over time and the nominal specification efficiently evolves, ensuring product quality over time.

In one illustrative embodiment, the present disclosure provides a spatial adhesive mapping method, including: identifying a part of a vehicle; applying an adhesive bead to the part; generating a three-dimensional adhesive map of the adhesive bead; and comparing the three-dimensional adhesive map to a three-dimensional adhesive envelope to determine if the adhesive bead is acceptable or unacceptable. The spatial adhesive mapping method may further include discarding the part when it is determined that the adhesive bead is unacceptable based on the comparison. The spatial adhesive mapping method may further include: performing a teardown inspection of the part to determine if the adhesive bead is acceptable or unacceptable; validating the three-dimensional adhesive envelope when it is determined that the adhesive bead is acceptable based on the teardown inspection; and modifying the three-dimensional adhesive envelope when it is determined that the adhesive bead is unacceptable based on the teardown inspection. The three-dimensional adhesive map indicates a location and a volume of the adhesive bead on the part. The spatial adhesive mapping method may further include modifying the three-dimensional adhesive envelope based on an external factor. The spatial adhesive mapping method may further include assembling the three-dimensional adhesive map with another three-dimensional adhesive map to generate a three-dimensional adhesive map for a vehicle sub-assembly, a vehicle assembly, or the vehicle. The spatial adhesive mapping method may further include storing the three-dimensional adhesive map in a memory as part of a library of three-dimensional adhesive maps.

In another illustrative embodiment, the present disclosure provides a non-transitory computer readable medium including instructions stored in a memory and executed by a processor to perform spatial adhesive mapping method steps including: identifying a part of a vehicle; applying an adhesive bead to the part; generating a three-dimensional adhesive map of the adhesive bead; and comparing the three-dimensional adhesive map to a three-dimensional adhesive envelope to determine if the adhesive bead is acceptable or unacceptable. The steps may further include advising discarding the part when it is determined that the adhesive bead is unacceptable based on the comparison. The steps may further include: receiving results of a teardown inspection of the part to determine if the adhesive bead is acceptable or unacceptable; validating the three-dimensional adhesive envelope when it is determined that the adhesive bead is acceptable based on the teardown inspection; and modifying the three-dimensional adhesive envelope when it is determined that the adhesive bead is unacceptable based on the teardown inspection. The three-dimensional adhesive map indicates a location and a volume of the adhesive bead on the part. The steps may further include modifying the three-dimensional adhesive envelope based on an external factor. The steps may further include assembling the three-dimensional adhesive map with another three-dimensional adhesive map to generate a three-dimensional adhesive map for a vehicle sub-assembly, a vehicle assembly, or the vehicle. The steps may further include storing the three-dimensional adhesive map in a memory as part of a library of three-dimensional adhesive maps.

In a further illustrative embodiment, the present disclosure provides a spatial adhesive mapping system, including: an identification sensor system operable for identifying a part of a vehicle; an adhesive application system operable for applying an adhesive bead to the part; an imaging and location sensor system operable for generating a three-dimensional adhesive map of the adhesive bead; and a spatial adhesive mapping module stored in a memory and executed by a processor, where the spatial adhesive mapping module is operable for comparing the three-dimensional adhesive map to a three-dimensional adhesive envelope to determine if the adhesive bead is acceptable or unacceptable. The spatial adhesive mapping module may further be operable for: receiving results of a teardown inspection of the part to determine if the adhesive bead is acceptable or unacceptable; validating the three-dimensional adhesive envelope when it is determined that the adhesive bead is acceptable based on the teardown inspection; and modifying the three-dimensional adhesive envelope when it is determined that the adhesive bead is unacceptable based on the teardown inspection. The three-dimensional adhesive map indicates a location and a volume of the adhesive bead on the part. The spatial adhesive mapping module may further be operable for modifying the three-dimensional adhesive envelope based on an external factor. The spatial adhesive mapping module may further be operable for assembling the three-dimensional adhesive map with another three-dimensional adhesive map to generate a three-dimensional adhesive map for a vehicle sub-assembly, a vehicle assembly, or the vehicle. The spatial adhesive mapping module may further be operable for storing the three-dimensional adhesive map in the memory as part of a library of three-dimensional adhesive maps.

### BRIEF DESCRIPTION OF THE DRAWINGS

The present disclosure is illustrated and described herein with reference to the various drawings, in which like reference numbers are used to denote like system components/method steps, as appropriate, and in which:

FIG. 1 is a schematic diagram illustrating an ideal adhesive bead distribution for a representative vehicle;

FIG. 2 is a schematic diagram illustrating an acceptable adhesive bead distribution for a representative vehicle, differing slightly from the ideal adhesive bead distribution of FIG. 1, with further variation possibly resulting in an unacceptable adhesive bead distribution;

FIG. 3 is a flowchart illustrating one embodiment of the spatial adhesive mapping method of the present disclosure;

FIG. 4 is a schematic diagram illustrating one embodiment of the spatial adhesive mapping system of the present disclosure;

FIG. 5 is a network diagram illustrating a cloud-based system for implementing the various systems and methods of the present disclosure;

FIG. 6 is a block diagram illustrating a server that may be used in the cloud-based system of FIG. 5 or stand-alone; and

FIG. 7 is a block diagram illustrating a user device that may be used in the cloud-based system of FIG. 5 or stand-alone.

### DETAILED DESCRIPTION

Again, the present disclosure provides improved spatial adhesive mapping methods and systems. The principles and concepts of the present disclosure may be applied in other vehicle manufacturing and other contexts as well. Using imaging and location sensors and systems, the spatial adhesive mapping methods and systems of the present disclosure map, in three dimensions, applied adhesive beads as they are applied on identified parts. These stored 3D adhesive bead maps are compared to nominal maps. Periodic teardowns are then used to identify problems and adjust the nominal maps as appropriate. In this manner, big data may be used to improve quality constantly over time. Imaging and visual aids are used to ensure location and volume accuracy in real time, and stored maps are used to provide feedback that enhances quality over time. The need for teardowns is minimized and problems and affected products can be identified and remedied or recalled more quickly.

Instead of simply monitoring an applied adhesive bead in terms of location and volume and checking the accuracy and effectiveness of such applied adhesive beads periodically via teardowns, the spatial adhesive mapping methods and systems of the present disclosure generate 3D adhesive bead maps for each identified part as applied, in real time, in terms of location and volume (including height, width, and shape). These 3D adhesive bead maps are stored and compared to nominal maps to ensure ongoing 3D envelope compliance. If a 3D adhesive bead map is out of compliance, a teardown may be performed. If the teardown results are subsequently determined to be unacceptable, then the associated part may be scrapped, along with all similar identified parts having similar 3D adhesive bead maps. If the teardown results are subsequently determined to be acceptable, then the associated part may be used and the nominal 3D envelope may be updated and used as a standard for subsequent parts. In this manner, feedback is used to provide and ensure an optimal nominal 3D envelope in real time and over time-replacing the conventional 2D location and volume (i.e., adhesive cylinder displacement) monitoring methodology versus a static predetermined specification. A library of pass/fail product configurations is thus efficiently created over time and the nominal specification efficiently evolves, ensuring product quality over time.

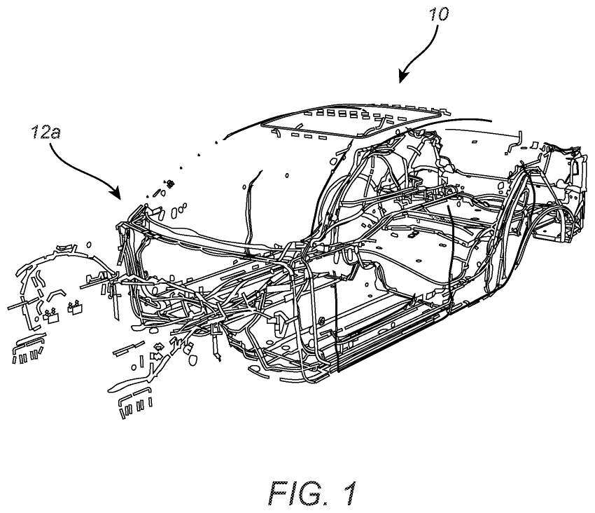

FIG. 1 is a schematic diagram illustrating an ideal adhesive bead distribution 12a for a representative vehicle 10, effectively representing the ideal 3D adhesive bead map 12a for all parts of the representative vehicle 10.

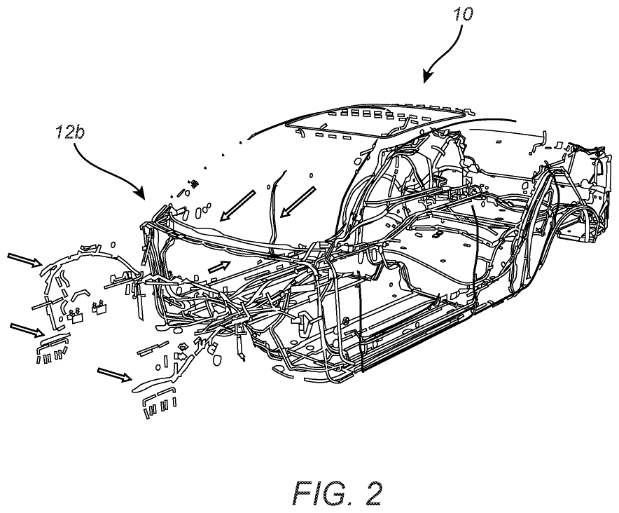

FIG. 2 is a schematic diagram illustrating an acceptable adhesive bead distribution 12b for a representative vehicle 10, effectively representing an acceptable 3D adhesive bead map 12b for all parts of the representative vehicle 10, differing slightly from the ideal adhesive bead distribution 12a of FIG. 1, with further variation possibly resulting in an unacceptable adhesive bead distribution. Variation between the acceptable adhesive bead distribution 12b and the ideal adhesive bead distribution 12a is indicated by the arrows provided in FIG. 2, for example.

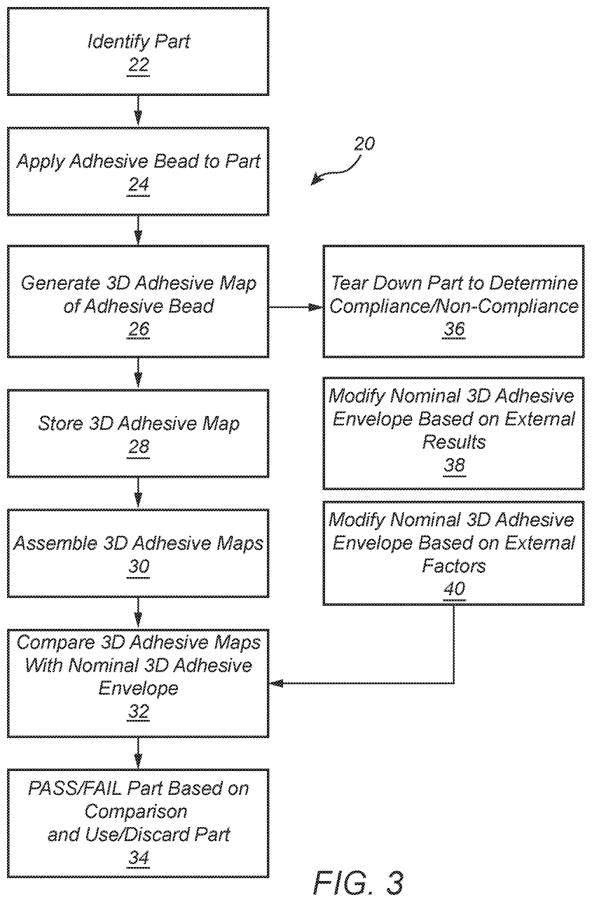

Referring now specifically to FIG. 3, the spatial adhesive mapping method 20 of the present disclosure first includes, given a part to which an adhesive bead is to be applied using an adhesive application system (step 24), identifying the part using an identification sensor and/or system (step 22). For example, the part may be tagged with a radio-frequency identification (RFID) tag, optical tag (e.g., barcode or quick-response (QR code)), or the like and the identification sensor and/or system may be an RFID reader, optical reader (e.g., optical scanner or camera), or the like. Such identification sensors and/or systems are well known to those of ordinary skill in the art and are not described in further detail herein. As the adhesive bead is applied to the part by the adhesive application system, such as to a metal sheet to which another metal sheet is subsequently to be joined, the spatial adhesive mapping method further includes generating a 3D adhesive map of the adhesive bead (step 26). This 3D adhesive map includes the location of the adhesive bead on the part as determined by imaging and location sensors and/or systems, as well as the volume (i.e., height, width, and shape) of the adhesive bead on the part as determined by the imaging and location sensors and/or systems. The 3D adhesive map is a model of the adhesive bead as applied to the part, including its dimensions. For example, the spatial adhesive mapping module may include a cross-section function that determines the cross-section of the adhesive bead at each location along the length of the bead, and thus at each location on the part. Locations may be determined based on an absolute frame of reference, or with respect to different features of or provided with respect to the part. The 3D adhesive map is then tagged with the determined part identification in a memory associated with the spatial adhesive mapping module, which may be local and/or remote (step 28). This may be done for each part associated with a vehicle, and the parts may be assembled to generate a 3D adhesive map for each vehicle sub-system, system, or vehicle (step 30). In this manner, a library of 3D adhesive maps is generated, tagged to identified parts, vehicle sub-systems, systems, and vehicles.

In an initial case, a teardown may then be conducted to determine if the adhesive bead associated with a given 3D adhesive map is acceptable (PASS) or unacceptable (FAIL) (step 36). If the 3D adhesive map is PASS, then the 3D adhesive map may be set as an acceptable 3D adhesive envelope or used to validate or modify the acceptable 3D adhesive envelope against which subsequent 3D adhesive maps are assessed (step 38), essentially representing the new nominal adhesive application specification envelope. If the 3D adhesive map is FAIL, then the 3D adhesive map may be set as an unacceptable 3D adhesive envelope or used to invalidate or modify the acceptable 3D adhesive envelope against which subsequent 3D adhesive maps are assessed (step 38), essentially representing the new nominal adhesive application specification envelope. In this manner, every time a 3D adhesive map is generated and stored in the library and an associated teardown is performed, the 3D adhesive map provides a new data point for validating, invalidating, and/or refining the current acceptable 3D adhesive envelope and nominal adhesive application specification envelope used to assess subsequent adhesive applications and 3D adhesive maps. In this manner, given multiple passing and failing 3D adhesive maps, boundaries of the acceptable 3D adhesive envelope used going forward are established and refined, in terms of location and volume.

In subsequent cases, 3D adhesive maps are generated, stored, and assessed against the established and refined 3D adhesive envelope (step 32), either resulting a PASS and usage of the associated part or a FAIL and non-usage of the associated part based only on compliance with the established and refined 3D adhesive envelope (step 34), with the 3D adhesive models being stored for each identified part, vehicle sub-system, system, and/or vehicle.

Given the robustness of this recording and archiving approach, 3D adhesive model parameters that will pass or fail can be incorporated into the 3D adhesive envelope standard benchmark based on external factors (step 40), such as engineering standards, calculations, and/or simulations, determined exceptions/allowances, preferred tolerances, etc., all of which may be received and incorporated into the 3D adhesive envelope standard by the spatial adhesive mapping module and software. For example, an adhesive bead that is outside of a spot weld on a part is generally subtracted from identified defects. Thus, the 3D adhesive envelope may be modified by the spatial adhesive mapping module and software to identify such spot weld as a monument or the like such that this area is ignored in terms of defect analysis. The 3D adhesive envelope can be modified based on any number of such local and other considerations not directly associated with the 3D adhesive models stored in the library and associated teardown results, potentially collectively referred to herein as “extrinsic considerations.”

As alluded to herein above, via RFID tags or the like, records associated with any part or vehicle can be identified and assembled, such that the 3D adhesive model can be obtained for any singular part or collective vehicle sub-system, system, or vehicle. This can be used for quality control, to correlate to a contemporaneous or subsequent teardown, or for subsequent remedial actions/recall.

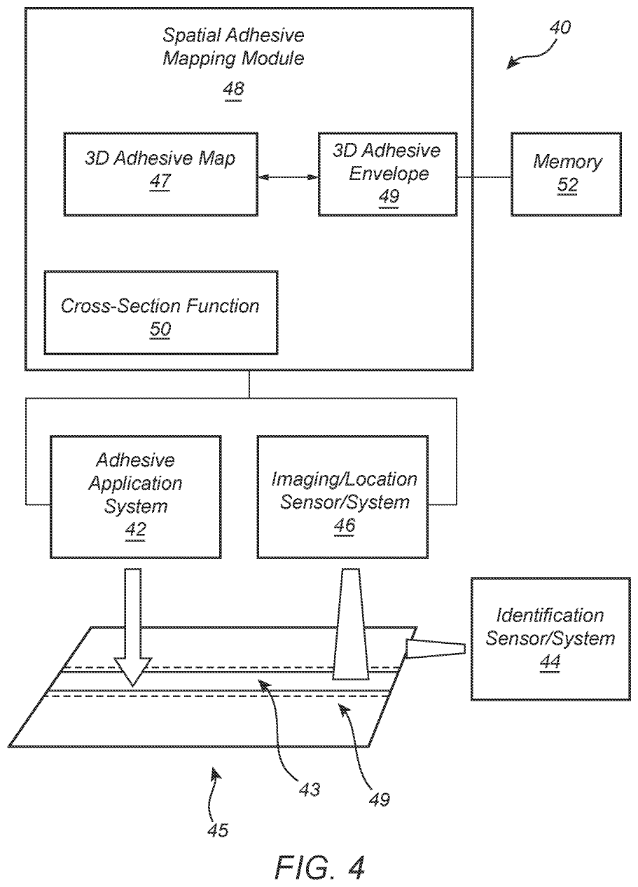

Referring now specifically to FIG. 4, the spatial adhesive mapping system 40 of the present disclosure includes the application system 42 for applying the adhesive bead 43 to the part 45 and the identification sensor and/or system 44 for identifying the part. For example, the part may be tagged with a RFID tag, optical tag (e.g., barcode or QR code), or the like and the identification sensor and/or system 44 may be an RFID reader, optical reader (e.g., optical scanner or camera), or the like. The application system 42 may include any suitable adhesive application devices, assemblies, and control systems. Such identification sensors and/or systems and application systems are well known to those of ordinary skill in the art and are not described in further detail herein. As the adhesive bead 43 is applied to the part by the adhesive application system 42, such as to a metal sheet to which another metal sheet is subsequently to be joined, the spatial adhesive mapping system 40 further includes imaging and location sensors and/or systems 46, such as a camera or other contour/surface/topography-imaging device, for generating the 3D adhesive map 47 of the adhesive bead 43. This 3D adhesive map 47 includes the location of the adhesive bead 43 on the part 45 as determined by the imaging and location sensors and/or systems 46, as well as the volume (i.e., height, width, and shape) of the adhesive bead 43 on the part 45 as determined by the imaging and location sensors and/or systems 46. The 3D adhesive map 47 is a model of the adhesive bead 43 as applied to the part 45, including its dimensions. For example, the spatial adhesive mapping module 48 of the spatial adhesive mapping system 40 may include a cross-section function 50 that determines the cross-section of the adhesive bead 43 at each location along the length of the bead 43, and thus at each location on the part 45. Locations may be determined based on an absolute frame of reference, or with respect to different features of or provided with respect to the part 45. The 3D adhesive map 47 is then tagged with the determined part identification in a memory 52 associated with the spatial adhesive mapping module 48, which may be local and/or remote. This may be done for each part 45 associated with a vehicle 10 (FIGS. 1 and 2), and the parts 45 may be assembled to generate a 3D adhesive map 47 for each vehicle sub-system, system, or vehicle 10. In this manner, a library of 3D adhesive maps 47 is generated, tagged to identified parts 45, vehicle sub-systems, systems, and vehicles 10.

Again, in an initial case, a teardown may then be conducted to determine if the adhesive bead 43 associated with a given 3D adhesive map 47 is acceptable (PASS) or unacceptable (FAIL). If the 3D adhesive map 47 is PASS, then the 3D adhesive map 47 may be set as an acceptable 3D adhesive envelope 49 or used to validate or modify the acceptable 3D adhesive envelope 49 against which subsequent 3D adhesive maps 47 are assessed, essentially representing the new nominal adhesive application specification envelope. If the 3D adhesive map 47 is FAIL, then the 3D adhesive map 47 may be set as an unacceptable 3D adhesive envelope 49 or used to invalidate or modify the acceptable 3D adhesive envelope 49 against which subsequent 3D adhesive maps 47 are assessed, essentially representing the new nominal adhesive application specification envelope. In this manner, every time a 3D adhesive map 47 is generated and stored in the library and an associated teardown is performed, the 3D adhesive map 47 provides a new data point for validating, invalidating, and/or refining the current acceptable 3D adhesive envelope 49 and nominal adhesive application specification envelope used to assess subsequent adhesive applications and 3D adhesive maps 47. In this manner, given multiple passing and failing 3D adhesive maps 47, boundaries of the acceptable 3D adhesive envelope 49 used going forward are established and refined, in terms of location and volume.

Again, in subsequent cases, 3D adhesive maps 47 are generated, stored, and assessed against the established and refined 3D adhesive envelope 49, either resulting a PASS and usage of the associated part 45 or a FAIL and non-usage of the associated part 45 based only on compliance with the established and refined 3D adhesive envelope 49, with the 3D adhesive models being stored for each identified part 45, vehicle sub-system, system, and/or vehicle 10.

Again, given the robustness of this recording and archiving approach, 3D adhesive model parameters that will pass or fail can be incorporated into the 3D adhesive envelope standard benchmark based on external factors, such as engineering standards, calculations, and/or simulations, determined exceptions/allowances, preferred tolerances, etc., all of which may be received and incorporated into the 3D adhesive envelope standard by the spatial adhesive mapping module 48 and software. For example, an adhesive bead 43 that is outside of a spot weld on a part 45 is generally subtracted from identified defects. Thus, the 3D adhesive envelope 49 may be modified by the spatial adhesive mapping module 48 and software to identify such spot weld as a monument or the like such that this area is ignored in terms of defect analysis. The 3D adhesive envelope 49 can be modified based on any number of such local and other considerations not directly associated with the 3D adhesive models stored in the library and associated teardown results, potentially collectively referred to herein as “extrinsic considerations.”

As alluded to herein above, via RFID tags or the like, records associated with any part 45 or vehicle 10 can be identified and assembled, such that the 3D adhesive model can be obtained for any singular part 45 or collective vehicle sub-system, system, or vehicle 10. This can be used for quality control, to correlate to a contemporaneous or subsequent teardown, or for subsequent remedial actions/recall.

It is to be recognized that, depending on the example, certain acts and/or events of any of the techniques described herein can be performed in a different sequence, may be added, merged, or left out altogether (e.g., not all described acts or events are necessary for the practice of the techniques). Moreover, in certain examples, acts and/or events may be performed concurrently, e.g., through multi-threaded processing, interrupt processing, or using multiple processors, rather than sequentially.

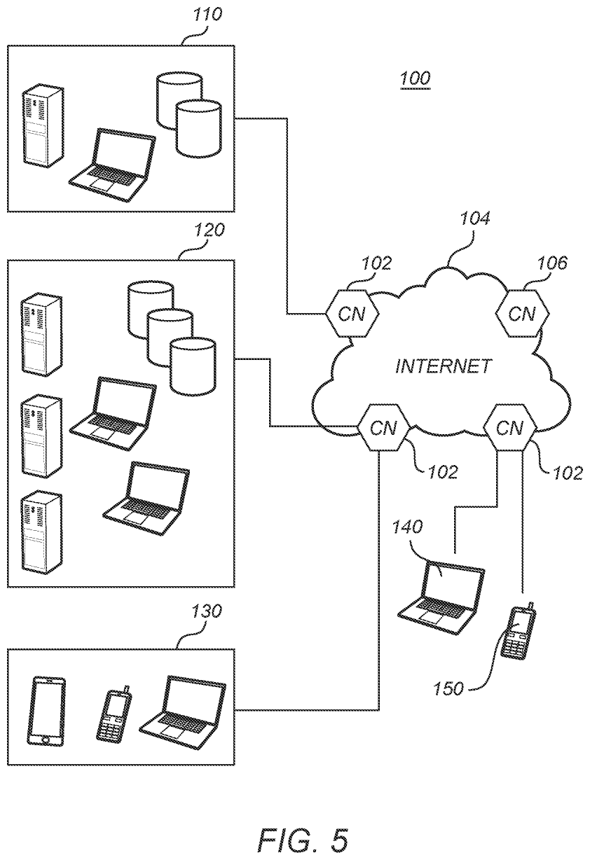

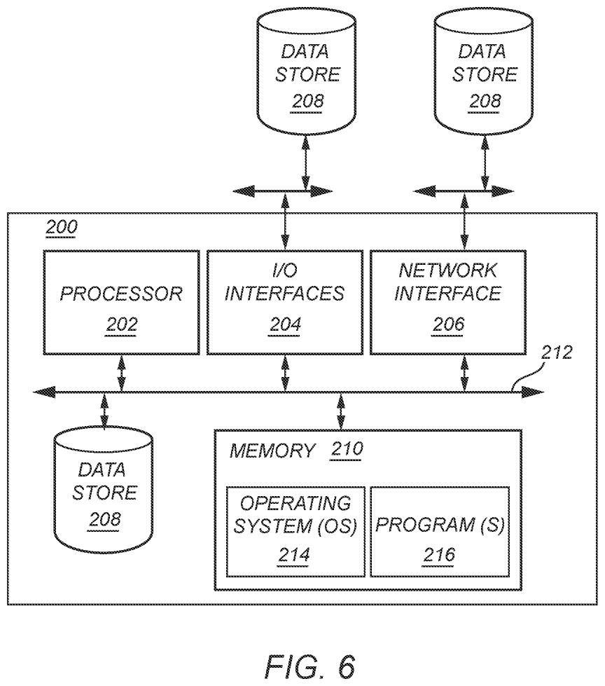

FIG. 5 is a network diagram illustrating a cloud-based system 100 for implementing various cloud-based services of the present disclosure. The cloud-based system 100 includes one or more cloud nodes (CNs) 102 communicatively coupled to the Internet 104 or the like. The cloud nodes 102 may be implemented as a server 200 (as illustrated in FIG. 6) or the like and can be geographically diverse from one another, such as located at various data centers around the country or globe. Further, the cloud-based system 100 can include one or more central authority (CA) nodes 106, which similarly can be implemented as the server 200 and be connected to the CNs 102. For illustration purposes, the cloud-based system 100 can connect to a regional office 110, headquarters 120, various employee's locations 130, laptops/desktops 140, and mobile devices 150, each of which can be communicatively coupled to one of the CNs 102. These locations 110, 120, and 130, and devices 140 and 150 are shown for illustrative purposes, and those skilled in the art will recognize there are various access scenarios to the cloud-based system 100, all of which are contemplated herein. The devices 140 and 150 can be so-called “road warriors,” i.e., users off-site, on-the-road, etc. The cloud-based system 100 can be a private cloud, a public cloud, a combination of a private cloud and a public cloud (i.e., hybrid cloud), or the like.

Again, the cloud-based system 100 can provide any functionality through services, such as software-as-a-service (SaaS), platform-as-a-service, infrastructure-as-a-service, security-as-a-service, Virtual Network Functions (VNFs) in a Network Functions Virtualization (NFV) Infrastructure (NFVI), etc. to the locations 110, 120, and 130 and devices 140 and 150. Previously, the Information Technology (IT) deployment model included enterprise resources and applications stored within an enterprise network (i.e., physical devices), behind a firewall, accessible by employees on site or remote via Virtual Private Networks (VPNs), etc. The cloud-based system 100 is replacing the conventional deployment model. The cloud-based system 100 can be used to implement these services in the cloud without requiring the physical devices and management thereof by enterprise IT administrators.

Cloud computing systems and methods abstract away physical servers, storage, networking, etc., and instead offer these as on-demand and elastic resources. The National Institute of Standards and Technology (NIST) provides a concise and specific definition which states that cloud computing is a model for enabling convenient, on-demand network access to a shared pool of configurable computing resources (e.g., networks, servers, storage, applications, and services) that can be rapidly provisioned and released with minimal management effort or service provider interaction. Cloud computing differs from the classic client-server model by providing applications from a server that are executed and managed by a client's web browser or the like, with no installed client version of an application required. Centralization gives cloud service providers complete control over the versions of the browser-based and other applications provided to clients, which removes the need for version upgrades or license management on individual client computing devices. The phrase “software as a service” (SaaS) is sometimes used to describe application programs offered through cloud computing. A common shorthand for a provided cloud computing service (or even an aggregation of all existing cloud services) is “the cloud.” The cloud-based system 100 is illustrated herein as one example embodiment of a cloud-based system, and those of ordinary skill in the art will recognize the systems and methods described herein are not necessarily limited thereby.

FIG. 6 is a block diagram illustrating a server 200, which may be used in the cloud-based system 100 (FIG. 6), in other systems, or stand-alone. For example, the CNs 102 (FIG. 5) and the central authority nodes 106 (FIG. 5) may be formed as one or more of the servers 200. The server 200 may be a digital computer that, in terms of hardware architecture, generally includes a processor 202, input/output (I/O) interfaces 204, a network interface 206, a data store 208, and memory 210. It should be appreciated by those of ordinary skill in the art that FIG. 6 depicts the server 200 in an oversimplified manner, and a practical embodiment may include additional components and suitably configured processing logic to support known or conventional operating features that are not described in detail herein. The components (202, 204, 206, 208, and 210) are communicatively coupled via a local interface 212. The local interface 212 may be, for example, but is not limited to, one or more buses or other wired or wireless connections, as is known in the art. The local interface 212 may have additional elements, which are omitted for simplicity, such as controllers, buffers (caches), drivers, repeaters, and receivers, among many others, to enable communications. Further, the local interface 212 may include address, control, and/or data connections to enable appropriate communications among the aforementioned components.

The processor 202 is a hardware device for executing software instructions. The processor 202 may be any custom made or commercially available processor, a central processing unit (CPU), an auxiliary processor among several processors associated with the server 200, a semiconductor-based microprocessor (in the form of a microchip or chipset), or generally any device for executing software instructions. When the server 200 is in operation, the processor 202 is configured to execute software stored within the memory 210, to communicate data to and from the memory 210, and to generally control operations of the server 200 pursuant to the software instructions. The I/O interfaces 204 may be used to receive user input from and/or for providing system output to one or more devices or components.

The network interface 206 may be used to enable the server 200 to communicate on a network, such as the Internet 104 (FIG. 5). The network interface 206 may include, for example, an Ethernet card or adapter (e.g., 10BaseT, Fast Ethernet, Gigabit Ethernet, or 10 GbE) or a Wireless Local Area Network (WLAN) card or adapter (e.g., 802.11a/b/g/n/ac). The network interface 206 may include address, control, and/or data connections to enable appropriate communications on the network. A data store 208 may be used to store data. The data store 208 may include any of volatile memory elements (e.g., random access memory (RAM, such as DRAM, SRAM, SDRAM, and the like)), nonvolatile memory elements (e.g., ROM, hard drive, tape, CDROM, and the like), and combinations thereof. Moreover, the data store 208 may incorporate electronic, magnetic, optical, and/or other types of storage media. In one example, the data store 208 may be located internal to the server 200, such as, for example, an internal hard drive connected to the local interface 212 in the server 200. Additionally, in another embodiment, the data store 208 may be located external to the server 200 such as, for example, an external hard drive connected to the I/O interfaces 204 (e.g., a SCSI or USB connection). In a further embodiment, the data store 208 may be connected to the server 200 through a network, such as, for example, a network-attached file server.

The memory 210 may include any of volatile memory elements (e.g., random access memory (RAM, such as DRAM, SRAM, SDRAM, etc.)), nonvolatile memory elements (e.g., ROM, hard drive, tape, CDROM, etc.), and combinations thereof. Moreover, the memory 210 may incorporate electronic, magnetic, optical, and/or other types of storage media. Note that the memory 210 may have a distributed architecture, where various components are situated remotely from one another but can be accessed by the processor 202. The software in memory 210 may include one or more software programs, each of which includes an ordered listing of executable instructions for implementing logical functions. The software in the memory 210 includes a suitable operating system (O/S) 214 and one or more programs 216. The operating system 214 essentially controls the execution of other computer programs, such as the one or more programs 216, and provides scheduling, input-output control, file and data management, memory management, and communication control and related services. The one or more programs 216 may be configured to implement the various processes, algorithms, methods, techniques, etc. described herein.

It will be appreciated that some embodiments described herein may include one or more generic or specialized processors (“one or more processors”) such as microprocessors; central processing units (CPUs); digital signal processors (DSPs); customized processors such as network processors (NPs) or network processing units (NPUs), graphics processing units (GPUs), or the like; field programmable gate arrays (FPGAs); and the like along with unique stored program instructions (including both software and firmware) for control thereof to implement, in conjunction with certain non-processor circuits, some, most, or all of the functions of the methods and/or systems described herein. Alternatively, some or all functions may be implemented by a state machine that has no stored program instructions, or in one or more application-specific integrated circuits (ASICs), in which each function or some combinations of certain of the functions are implemented as custom logic or circuitry. Of course, a combination of the aforementioned approaches may be used. For some of the embodiments described herein, a corresponding device in hardware and optionally with software, firmware, and a combination thereof can be referred to as “circuitry configured or adapted to,” “logic configured or adapted to,” etc. perform a set of operations, steps, methods, processes, algorithms, functions, techniques, etc. on digital and/or analog signals as described herein for the various embodiments.

Moreover, some embodiments may include a non-transitory computer-readable medium having computer-readable code stored thereon for programming a computer, server, appliance, device, processor, circuit, etc. each of which may include a processor to perform functions as described and claimed herein. Examples of such computer-readable mediums include, but are not limited to, a hard disk, an optical storage device, a magnetic storage device, a Read-Only Memory (ROM), a Programmable Read-Only Memory (PROM), an Erasable Programmable Read-Only Memory (EPROM), an Electrically Erasable Programmable Read-Only Memory (EEPROM), flash memory, and the like. When stored in the non-transitory computer-readable medium, software can include instructions executable by a processor or device (e.g., any type of programmable circuitry or logic) that, in response to such execution, cause a processor or the device to perform a set of operations, steps, methods, processes, algorithms, functions, techniques, etc. as described herein for the various embodiments.

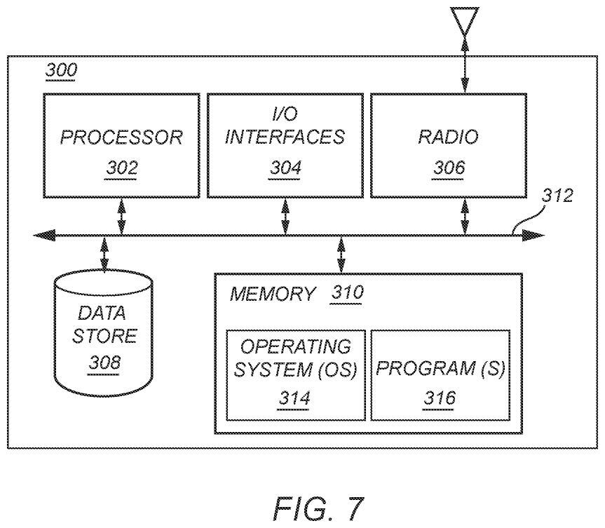

FIG. 7 is a block diagram illustrating a user device 300, which may be used in the cloud-based system 100 (FIG. 5), as part of a network, or stand-alone. Again, the user device 300 can be a vehicle, a smartphone, a tablet, a smartwatch, an Internet of Things (IoT) device, a laptop, a virtual reality (VR) headset, etc. The user device 300 can be a digital device that, in terms of hardware architecture, generally includes a processor 302, I/O interfaces 304, a radio 306, a data store 308, and memory 310. It should be appreciated by those of ordinary skill in the art that FIG. 7 depicts the user device 300 in an oversimplified manner, and a practical embodiment may include additional components and suitably configured processing logic to support known or conventional operating features that are not described in detail herein. The components (302, 304, 306, 308, and 310) are communicatively coupled via a local interface 312. The local interface 312 can be, for example, but is not limited to, one or more buses or other wired or wireless connections, as is known in the art. The local interface 312 can have additional elements, which are omitted for simplicity, such as controllers, buffers (caches), drivers, repeaters, and receivers, among many others, to enable communications. Further, the local interface 312 may include address, control, and/or data connections to enable appropriate communications among the aforementioned components.

The processor 302 is a hardware device for executing software instructions. The processor 302 can be any custom made or commercially available processor, a CPU, an auxiliary processor among several processors associated with the user device 300, a semiconductor-based microprocessor (in the form of a microchip or chipset), or generally any device for executing software instructions. When the user device 300 is in operation, the processor 302 is configured to execute software stored within the memory 310, to communicate data to and from the memory 310, and to generally control operations of the user device 300 pursuant to the software instructions. In an embodiment, the processor 302 may include a mobile optimized processor such as optimized for power consumption and mobile applications. The I/O interfaces 304 can be used to receive user input from and/or for providing system output. User input can be provided via, for example, a keypad, a touch screen, a scroll ball, a scroll bar, buttons, a barcode scanner, and the like. System output can be provided via a display device such as a liquid crystal display (LCD), touch screen, and the like.

The radio 306 enables wireless communication to an external access device or network. Any number of suitable wireless data communication protocols, techniques, or methodologies can be supported by the radio 306, including any protocols for wireless communication. The data store 308 may be used to store data. The data store 308 may include any of volatile memory elements (e.g., random access memory (RAM, such as DRAM, SRAM, SDRAM, and the like)), nonvolatile memory elements (e.g., ROM, hard drive, tape, CDROM, and the like), and combinations thereof. Moreover, the data store 308 may incorporate electronic, magnetic, optical, and/or other types of storage media.

Again, the memory 310 may include any of volatile memory elements (e.g., random access memory (RAM, such as DRAM, SRAM, SDRAM, etc.)), nonvolatile memory elements (e.g., ROM, hard drive, etc.), and combinations thereof. Moreover, the memory 310 may incorporate electronic, magnetic, optical, and/or other types of storage media. Note that the memory 310 may have a distributed architecture, where various components are situated remotely from one another, but can be accessed by the processor 302. The software in memory 310 can include one or more software programs, each of which includes an ordered listing of executable instructions for implementing logical functions. In the example of FIG. 7, the software in the memory 310 includes a suitable operating system 314 and programs 316. The operating system 314 essentially controls the execution of other computer programs and provides scheduling, input-output control, file and data management, memory management, and communication control and related services. The programs 316 may include various applications, add-ons, etc. configured to provide end user functionality with the user device 300. For example, example programs 316 may include, but not limited to, a web browser, social networking applications, streaming media applications, games, mapping and location applications, electronic mail applications, financial applications, and the like. In a typical example, the end-user typically uses one or more of the programs 316 along with a network, such as the cloud-based system 100 (FIG. 5).

Again, the present disclosure provides improved spatial adhesive mapping methods and systems. The principles and concepts of the present disclosure may be applied in other vehicle manufacturing and other contexts as well. Using imaging and location sensors and systems, the spatial adhesive mapping methods and systems of the present disclosure map, in three dimensions, applied adhesive beads as they are applied on identified parts. These stored 3D adhesive bead maps are compared to nominal maps. Periodic teardowns are then used to identify problems and adjust the nominal maps as appropriate. In this manner, big data may be used to improve quality constantly over time. Imaging and visual aids are used to ensure location and volume accuracy in real time, and stored maps are used to provide feedback that enhances quality over time. The need for teardowns is minimized and problems and affected products can be identified and remedied or recalled more quickly.

Instead of simply monitoring an applied adhesive bead in terms of location and volume and checking the accuracy and effectiveness of such applied adhesive beads periodically via teardowns, the spatial adhesive mapping methods and systems of the present disclosure generate 3D adhesive bead maps for each identified part as applied, in real time, in terms of location and volume (including height, width, and shape). These 3D adhesive bead maps are stored and compared to nominal maps to ensure ongoing 3D envelope compliance. If a 3D adhesive bead map is out of compliance, a teardown may be performed. If the teardown results are subsequently determined to be unacceptable, then the associated part may be scrapped, along with all similar identified parts having similar 3D adhesive bead maps. If the teardown results are subsequently determined to be acceptable, then the associated part may be used and the nominal 3D envelope may be updated and used as a standard for subsequent parts. In this manner, feedback is used to provide and ensure an optimal nominal 3D envelope in real time and over time-replacing the conventional 2D location and volume (i.e., adhesive cylinder displacement) monitoring methodology versus a static predetermined specification. A library of pass/fail product configurations is thus efficiently created over time and the nominal specification efficiently evolves, ensuring product quality over time.

Although the present disclosure is illustrated and described herein with reference to illustrative embodiments and specific examples thereof, it will be readily apparent to those of ordinary skill in the art that other embodiments and examples may perform similar functions and/or achieve like results. All such equivalent embodiments and examples are within the spirit and scope of the present disclosure, are contemplated thereby, and are intended to be covered by the following non-limiting claims for all purposes.

What is claimed is:

1. A spatial adhesive mapping method, comprising:
identifying a part of a vehicle;
applying an adhesive bead to the part;
generating a three-dimensional adhesive map of the adhesive bead; and
comparing the three-dimensional adhesive map to a three-dimensional adhesive envelope to determine if the adhesive bead is acceptable or unacceptable.

2. The spatial adhesive mapping method of claim 1, further comprising discarding the part when it is determined that the adhesive bead is unacceptable based on the comparison.

3. The spatial adhesive mapping method of claim 1, further comprising:
performing a teardown inspection of the part to determine if the adhesive bead is acceptable or unacceptable;
validating the three-dimensional adhesive envelope when it is determined that the adhesive bead is acceptable based on the teardown inspection; and
modifying the three-dimensional adhesive envelope when it is determined that the adhesive bead is unacceptable based on the teardown inspection.

4. The spatial adhesive mapping method of claim 1, wherein the three-dimensional adhesive map indicates a location and a volume of the adhesive bead on the part.

5. The spatial adhesive mapping method of claim 1, further comprising modifying the three-dimensional adhesive envelope based on an external factor.

6. The spatial adhesive mapping method of claim 1, further comprising assembling the three-dimensional adhesive map with another three-dimensional adhesive map to generate a three-dimensional adhesive map for a vehicle sub-assembly, a vehicle assembly, or the vehicle.

7. The spatial adhesive mapping method of claim 1, further comprising storing the three-dimensional adhesive map in a memory as part of a library of three-dimensional adhesive maps.

8. A non-transitory computer readable medium comprising instructions stored in a memory and executed by a processor to perform spatial adhesive mapping method steps comprising:
identifying a part of a vehicle;
applying an adhesive bead to the part;
generating a three-dimensional adhesive map of the adhesive bead; and
comparing the three-dimensional adhesive map to a three-dimensional adhesive envelope to determine if the adhesive bead is acceptable or unacceptable.

9. The non-transitory computer-readable medium of claim 8, the steps further comprising advising discarding the part when it is determined that the adhesive bead is unacceptable based on the comparison.

10. The non-transitory computer-readable medium of claim 8, the steps further comprising:
receiving results of a teardown inspection of the part to determine if the adhesive bead is acceptable or unacceptable;
validating the three-dimensional adhesive envelope when it is determined that the adhesive bead is acceptable based on the teardown inspection; and
modifying the three-dimensional adhesive envelope when it is determined that the adhesive bead is unacceptable based on the teardown inspection.

11. The non-transitory computer-readable medium of claim 8, wherein the three-dimensional adhesive map indicates a location and a volume of the adhesive bead on the part.

12. The non-transitory computer-readable medium of claim 8, the steps further comprising modifying the three-dimensional adhesive envelope based on an external factor.

13. The non-transitory computer-readable medium of claim 8, the steps further comprising assembling the three-dimensional adhesive map with another three-dimensional adhesive map to generate a three-dimensional adhesive map for a vehicle sub-assembly, a vehicle assembly, or the vehicle.

14. The non-transitory computer-readable medium of claim 8, the steps further comprising storing the three-dimensional adhesive map in a memory as part of a library of three-dimensional adhesive maps.

15. A spatial adhesive mapping system, comprising:
an identification sensor system operable for identifying a part of a vehicle;
an adhesive application system operable for applying an adhesive bead to the part;
an imaging and location sensor system operable for generating a three-dimensional adhesive map of the adhesive bead; and
a spatial adhesive mapping module stored in a memory and executed by a processor, wherein the spatial adhesive mapping module is operable for comparing the three-dimensional adhesive map to a three-dimensional adhesive envelope to determine if the adhesive bead is acceptable or unacceptable.

16. The spatial adhesive mapping system of claim 15, wherein the spatial adhesive mapping module is further operable for:
receiving results of a teardown inspection of the part to determine if the adhesive bead is acceptable or unacceptable;
validating the three-dimensional adhesive envelope when it is determined that the adhesive bead is acceptable based on the teardown inspection; and
modifying the three-dimensional adhesive envelope when it is determined that the adhesive bead is unacceptable based on the teardown inspection.

17. The spatial adhesive mapping system of claim 15, wherein the three-dimensional adhesive map indicates a location and a volume of the adhesive bead on the part.

18. The spatial adhesive mapping system of claim 15, wherein the spatial adhesive mapping module is further operable for modifying the three-dimensional adhesive envelope based on an external factor.

19. The spatial adhesive mapping system of claim 15, wherein the spatial adhesive mapping module is further operable for assembling the three-dimensional adhesive map with another three-dimensional adhesive map to generate a three-dimensional adhesive map for a vehicle sub-assembly, a vehicle assembly, or the vehicle.

20. The spatial adhesive mapping system of claim 15, wherein the spatial adhesive mapping module is further operable for storing the three-dimensional adhesive map in the memory as part of a library of three-dimensional adhesive maps.
